(19) United States
(12) Patent Application Publication
(10) Pub. No.: US 2025/0079238 A1
(43) Pub. Date: Mar. 6, 2025

(54) METHOD OF FABRICATING A SEMICONDUCTOR DEVICE

(71) Applicant: SAMSUNG ELECTRONICS CO., LTD., Suwon-si (KR)

(72) Inventors: Uihyoung LEE, Suwon-si (KR); Sang Ho JIN, Suwon-si (KR); Jongguk PARK, Suwon-si (KR); Yujin KIM, Suwon-si (KR); Hakyung YUN, Suwon-si (KR); Wonhee LEE, Suwon-si (KR)

(73) Assignee: SAMSUNG ELECTRONICS CO., LTD., Suwon-si (KR)

(21) Appl. No.: 18/762,397

(22) Filed: Jul. 2, 2024

(30) Foreign Application Priority Data
Sep. 1, 2023 (KR) 10-2023-0116373
Jan. 25, 2024 (KR) 10-2024-0011510

(51) Int. Cl. H01L 21/768; H01L 21/02

(52) U.S. Cl. CPC H01L 21/76846; H01L 21/02068; H01L 21/76871; H01L 21/76877

(57) ABSTRACT

A method of fabricating a semiconductor device is provided. The method includes: providing an interlayer dielectric layer with a trench on a substrate in a first substrate processing apparatus in a vacuum state; forming a first metal barrier in the trench while the substrate is in the first substrate processing apparatus; unloading the substrate from the first substrate processing apparatus and exposing the substrate to a non-vacuum environment; providing the substrate in a second substrate processing apparatus of a vacuum state; forming a second metal barrier in the trench in the second substrate processing apparatus; and forming a metal pattern to fill the trench.

### CROSS-REFERENCE TO RELATED APPLICATIONS

This application claims priority to Korean Patent Application Nos. 10-2023-0116373 and 10-2024-0011510, filed on Sep. 1, 2023 and Jan. 25, 2024, respectively, in the Korean Intellectual Property Office, the disclosures of which are incorporated by reference in their entireties.

### BACKGROUND

The present disclosure relates to a method of fabricating a semiconductor device, and in particular, to a method of fabricating a semiconductor device using a plurality of substrate processing apparatuses, which are configured to increase the efficiency in the fabrication process and improve the efficiency in space utilization.

A semiconductor device may be fabricated through several processes. The semiconductor fabrication process may include an operation of forming a fine metal pattern on a substrate. The metal pattern may be used to conduct electric signals, and as an integration density and complexity of the substrate increase, it is important to form the metal pattern finely and densely.

The metal pattern may be formed by forming a trench in an interlayer dielectric layer and filling the trench with a metal layer. However, if the metal layer is directly formed in the trench, due to a difference in concentration, a metallic element may be diffused in the substrate, and this may lead to deterioration in the quality of the semiconductor device or malfunction of the semiconductor device. Thus, a barrier may be formed in the trench to prevent the diffusion of the metallic element, and the metal pattern may be formed in the trench on the barrier.

### SUMMARY

One or more example embodiments provide a semiconductor fabrication method of removing an oxide layer, which is formed on a substrate when the substrate is transferred in a non-vacuum environment.

One or more example embodiments provide a semiconductor fabrication method of removing an oxide layer from a substrate using a sputtering process.

One or more example embodiments provide a semiconductor fabrication method of removing an oxide layer from a substrate through a chemical reaction process using a reactive gas or plasma.

One or more example embodiments provide a semiconductor fabrication method of increasing efficiency in space utilization using a plurality of substrate processing apparatuses.

One or more example embodiments provide a semiconductor fabrication method of diversifying the kind of a process chamber and increasing the efficiency of the fabrication process, using a plurality of substrate processing apparatuses.

According to an aspect of an example embodiment, a method of fabricating a semiconductor device includes: providing an interlayer dielectric layer with a trench on a substrate in a first substrate processing apparatus in a vacuum state; forming a first metal barrier in the trench while the substrate is in the first substrate processing apparatus; unloading the substrate from the first substrate processing apparatus and exposing the substrate to a non-vacuum environment; providing the substrate in a second substrate processing apparatus of a vacuum state; forming a second metal barrier in the trench in the second substrate processing apparatus; and forming a metal pattern to fill the trench.

According to an aspect of an example embodiment, a method of fabricating a semiconductor device includes: providing an interlayer dielectric layer with a trench on a substrate in a first substrate processing apparatus in a vacuum state; forming a deposition suppressing layer in the trench while the substrate is in the first substrate processing apparatus; unloading the substrate from the first substrate processing apparatus to expose the substrate to a non-vacuum state; providing the substrate in a second substrate processing apparatus of a vacuum state; forming a first metal barrier in the trench, in the second substrate processing apparatus; and forming a metal pattern to fill the trench.

### BRIEF DESCRIPTION OF DRAWINGS

The above and other aspects and features will be more apparent from the following description of example embodiments, taken in conjunction with the accompanying drawings, in which:

FIG. 1 is a perspective view illustrating a substrate processing system according to an example embodiment;

FIG. 2 is a perspective view illustrating a substrate processing system according to an example embodiment;

FIG. 3 is a flow chart illustrating a method of fabricating a semiconductor device according to an example embodiment;

FIG. 4 is a perspective view illustrating a substrate and an interlayer dielectric layer according to an example embodiment;

FIG. 5 is a sectional view illustrating a substrate and an interlayer dielectric layer according to an example embodiment;

FIG. 6 is a sectional view illustrating a substrate and an interlayer dielectric layer, on which a first metal barrier is formed, according to an example embodiment;

FIG. 7 is a sectional view illustrating a substrate and an interlayer dielectric layer, on which a first metal barrier and a second metal barrier are formed, according to an example embodiment;

FIG. 8 is a sectional view illustrating a substrate and an interlayer dielectric layer, on which a first metal barrier, a second metal barrier, and a seed layer are formed, according to an example embodiment;

FIG. 9 is a sectional view illustrating a substrate and an interlayer dielectric layer, on which a metal pattern on a seed layer is formed, according to an example embodiment;

FIG. 10 is a sectional view illustrating an atomic layer deposition (ALD) process, which is performed on a substrate and an interlayer dielectric layer, according to an example embodiment;

FIG. 11 is a sectional view illustrating an atomic layer deposition (ALD) process, which is performed on a substrate and an interlayer dielectric layer, according to an example embodiment;

FIG. 12 is a sectional view illustrating a physical vapor deposition (PVD) process, which is performed on a substrate and an interlayer dielectric layer, according to an example embodiment;

FIG. 13 is a sectional view illustrating a physical vapor deposition (PVD) process, which is performed on a substrate and an interlayer dielectric layer, according to an example embodiment;

FIG. 14 is a sectional view illustrating a substrate and an interlayer dielectric layer, on which a first metal barrier, a second metal barrier, a liner layer, and a seed layer are formed, according to an example embodiment;

FIG. 15 is a sectional view illustrating a chemical vapor deposition (CVD) process, which is performed on a substrate and an interlayer dielectric layer, according to an example embodiment;

FIG. 16 is a sectional view illustrating a chemical reaction process, which is performed on a substrate and an interlayer dielectric layer, according to an example embodiment;

FIG. 17 is a flow chart illustrating a method of fabricating a semiconductor device according to an example embodiment;

FIG. 18 is a sectional view illustrating a substrate and an interlayer dielectric layer, on which a deposition suppressing layer and a first metal barrier are formed, according to an example embodiment;

FIG. 19 is a sectional view illustrating a sputtering process, which is performed to remove an oxide layer from a substrate and an interlayer dielectric layer, according to an example embodiment;

FIG. 20 is a sectional view illustrating a substrate and an interlayer dielectric layer, on which a first metal barrier and a second metal barrier are formed, according to an example embodiment; and

FIG. 21 is a sectional view illustrating a substrate and an interlayer dielectric layer, on which a metal pattern on a second metal barrier is formed, according to an example embodiment.

### DETAILED DESCRIPTION

Example embodiments will be described in detail with reference to the accompanying drawings. Like reference numerals in the drawings denote like elements, and thus their description will be omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each example embodiment provided in the following description is not excluded from being associated with one or more features of another example or another example embodiment also provided herein or not provided herein but consistent with the present disclosure.

In the present application, the reference numbers D1, D2, and D3 will be used to denote a first direction, a second direction, and a third direction, respectively, which are not parallel to each other.

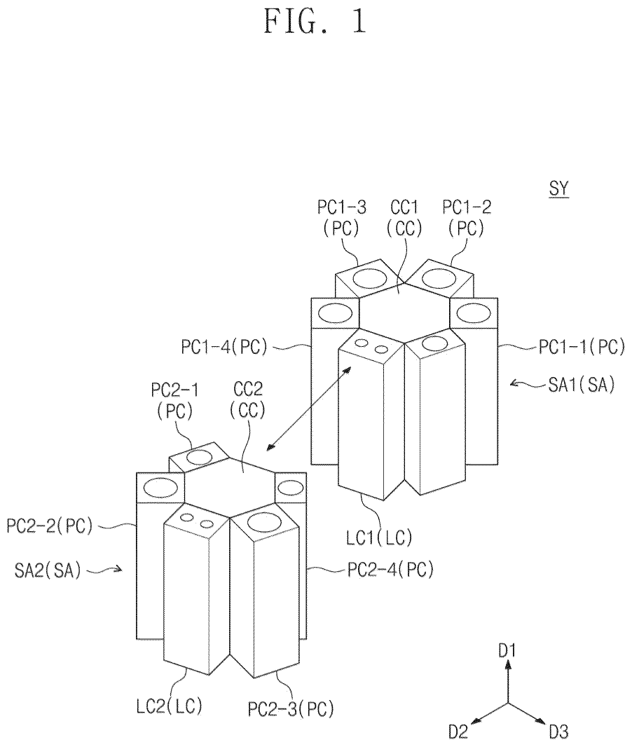

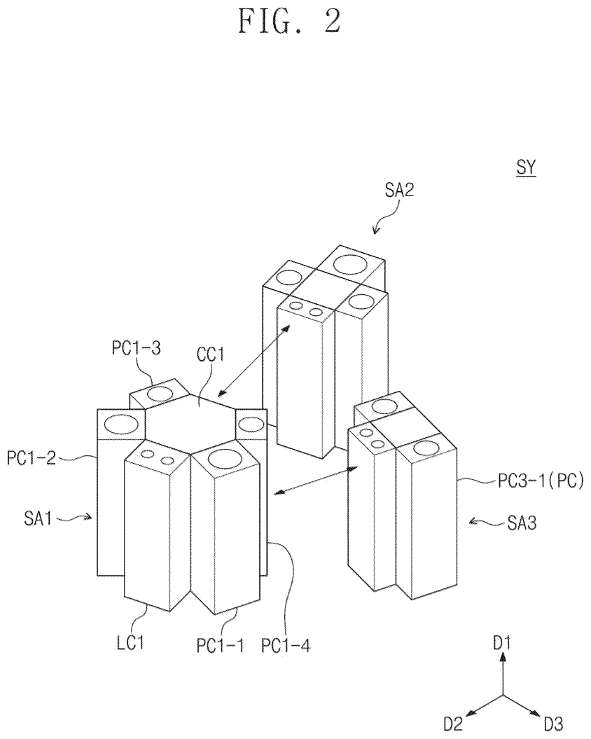

FIG. 1 is a perspective view illustrating a substrate processing system SY according to an example embodiment, and FIG. 2 is a perspective view illustrating the substrate processing system SY according to an example embodiment.

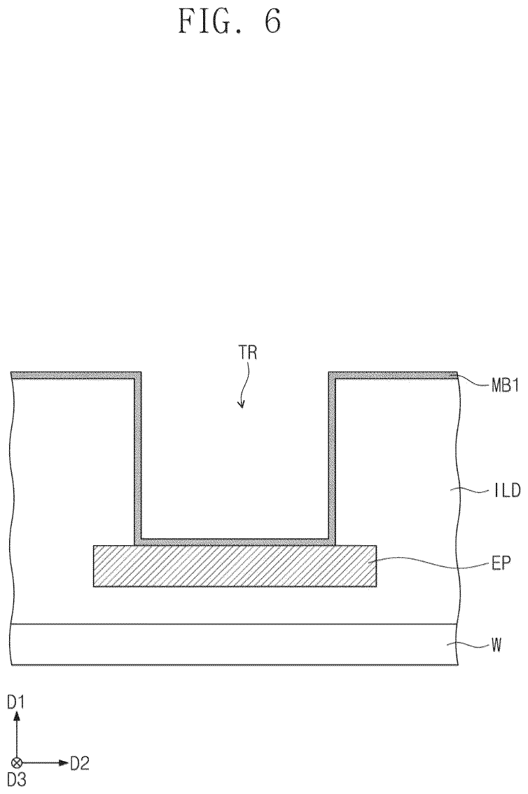

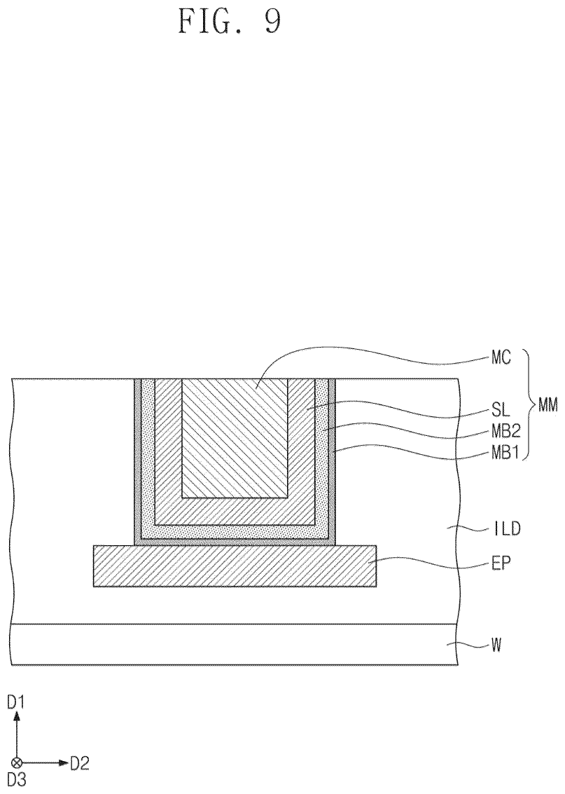

Referring to FIGS. 1 and 2, the substrate processing system SY may include a plurality of substrate processing apparatuses SA. A substrate W may be a silicon wafer, but example embodiments are not limited thereto. In an example embodiment, two or more substrate processing apparatuses SA may be provided. For example, the substrate processing system SY may include a first substrate processing apparatus SA1, a second substrate processing apparatus SA2, a third substrate processing apparatus SA3, and a fourth substrate processing apparatus. However, the number of the substrate processing apparatuses SA, which are included in the substrate processing system SY, may be variously changed. Each of the substrate processing apparatuses SA may include a center chamber CC, a load-lock chamber LC, and a plurality of process chambers PC. However, the structure of the substrate processing apparatus SA is not limited to this example and may further include other elements, which used for the substrate processing process. The first substrate processing apparatus SAI may include a (1-1)-th process chamber PC1-1, a (1-2)-th process chamber PC1-2, a (1-3)-th process chamber PC1-3, a first center chamber CC1, and a first load-lock chamber LC1. Similarly, the second substrate processing apparatus SA2 may include a (2-1)-th process chamber PC2-1, a (2-2)-th process chamber PC2-2, a (2-3)-th process chamber PC2-3, a second center chamber CC2, and a second load-lock chamber LC2. Each of the third substrate processing apparatus SA3 and the fourth substrate processing apparatus may include a process chamber PC, a center chamber CC, and a load-lock chamber LC in a similar manner. As the substrate W is transferred between different chambers or between different substrate processing apparatuses SA, elements which are formed on the substrate W may be transferred along with the substrate W. In the following description, if the substrate W is transferred, it may be understood that the elements, which are formed on the substrate W, are transferred along with the substrate W. The process chamber PC may be used to perform different processes from each other. One substrate processing apparatus SA may include a plurality of the process chambers PC that perform different processes from each other. However, example embodiments are not limited thereto, and one substrate processing apparatus SA may include a plurality of the process chambers PC that perform same process. For example, the first substrate processing apparatus SA1 may include two or more process chambers PC, which are used to form a first metal barrier MB1 of FIG. 6 in a trench TR of FIG. 6. The (1-1)-th process chamber PC1-1 and the (1-2)-th process chamber PC1-2 may be configured to perform a similar process. The process chamber PC may be used to perform several processes for forming a metal line MM of FIG. 9 on the substrate W and an interlayer dielectric layer ILD. The process chamber PC may be used to form the metal line MM in the trench TR. The metal line MM will be described in more detail below. In the following description, if the substrate W is not clearly described to be transferred from one substrate processing apparatus SA to another substrate processing apparatus SA, it may be understood that a relevant process is performed within the same substrate processing apparatus SA. In the case where several processes are performed on the substrate W in one substrate processing apparatus SA, it may be understood that the processes are performed in different process chambers PC from each other. Hereinafter, the process chamber PC will be described in more detail with reference to FIGS. 1 and 2. Various processes, which are performed using the process chamber PC, will be described in more detail below.

The center chamber CC may be used to transfer the substrate W from the process chamber PC to the process chamber PC, and from one process chamber PC to another process chamber PC. For example, the first center chamber CC1 may be used to move the substrate W from the (1-1)-th process chamber PC1-1 to the (1-3)-th process chamber PC1-3, without breaking a vacuum state.

The load-lock chamber LC may be used to load the substrate W from the outside to the center chamber CC. The process and center chambers PC and CC may be configured to maintain a high vacuum state. The load-lock chamber LC may be used to transfer the substrate W into the substrate processing apparatus SA, without breaking the high vacuum state of the process and center chambers PC and CC. In the case where the substrate W is provided in the load-lock chamber LC, a pump may be used to change an inner space of the load-lock chamber LC to a low vacuum state. The substrate W may be transferred from the load-lock chamber LC at a low vacuum state into the center and process chambers CC and PC at a high vacuum state. It may take a long time to change inner spaces of the process and center chambers PC and CC from an atmospheric pressure state to a high vacuum state. In the case where the load-lock chamber LC is used to load and unload the substrate W, it may be possible to reduce time and energy required to maintain the process and center chambers PC and CC to a high vacuum state.

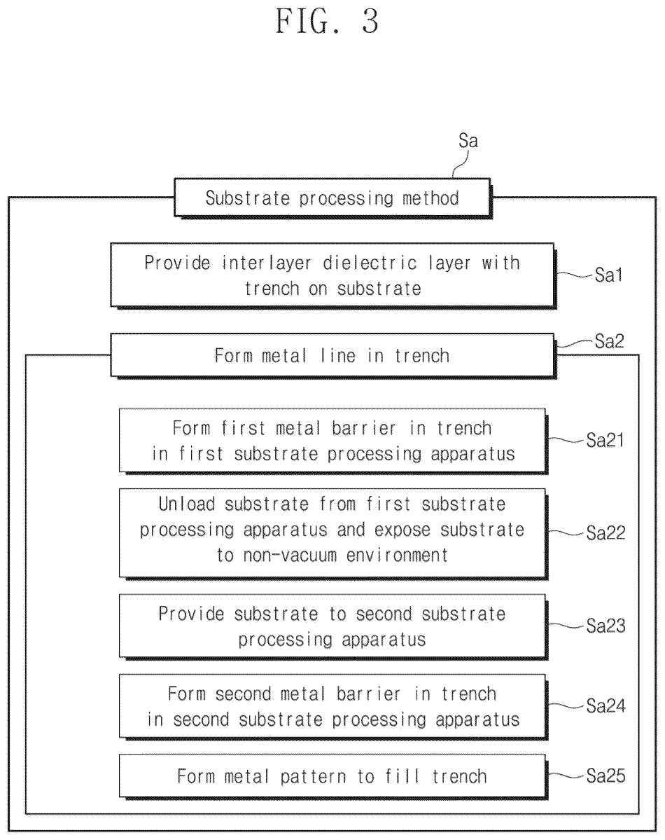

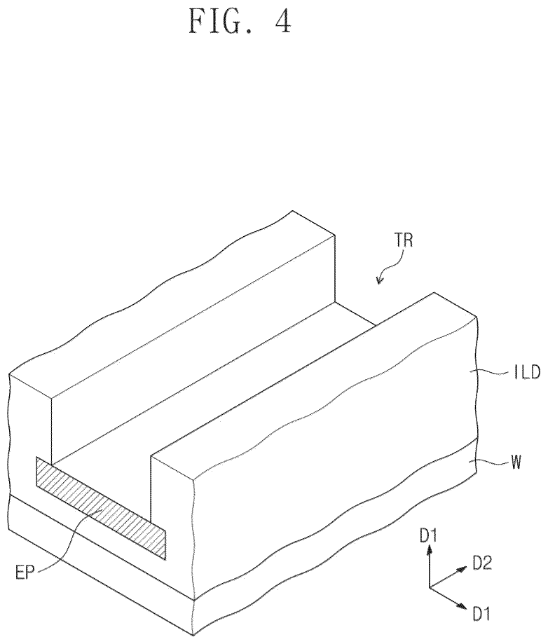

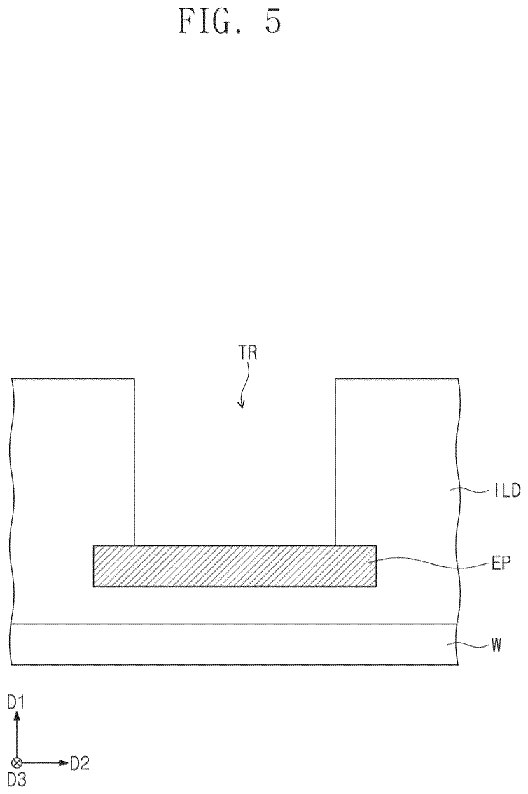

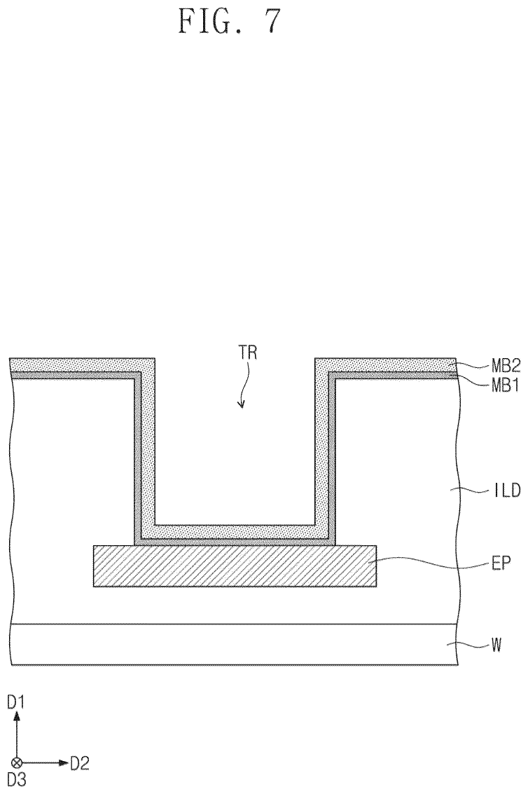

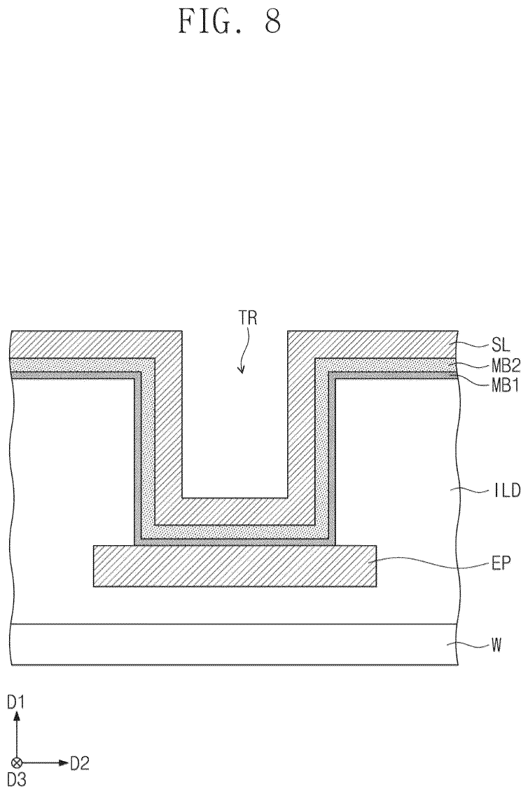

FIG. 3 is a flow chart illustrating a method Sa of fabricating a semiconductor device according to an example embodiment, FIG. 4 is a perspective view illustrating the substrate W and the interlayer dielectric layer ILD according to an example embodiment, FIG. 5 is a sectional view illustrating the substrate W and the interlayer dielectric layer ILD according to an example embodiment, FIG. 6 is a sectional view illustrating the substrate W and the interlayer dielectric layer ILD, on which the first metal barrier MB1 is formed, according to an example embodiment, FIG. 7 is a sectional view illustrating the substrate W and the interlayer dielectric layer ILD, on which the first metal barrier MB1 and a second metal barrier MB2 are formed, according to an example embodiment, FIG. 8 is a sectional view illustrating the substrate W and the interlayer dielectric layer ILD, on which the first metal barrier MB1, the second metal barrier MB2, and a seed layer SL are formed, according to an example embodiment, and FIG. 9 is a sectional view illustrating the substrate W and the interlayer dielectric layer ILD, on which a metal pattern MC on the seed layer SL are formed, according to an example embodiment.

Referring to FIG. 3, the fabrication method Sa may include providing the interlayer dielectric layer ILD with the trench TR on the substrate W (in operation Sal) and forming the metal line MM in the trench TR (in operation Sa2). The formation of the metal line MM (in operation Sa2) may include forming the first metal barrier MB1 in the trench TR using the first substrate processing apparatus SA1 (in operation Sa21), unloading the substrate W from the first substrate processing apparatus SA1 and exposing the substrate W to a non-vacuum environment (in operation Sa22), transferring the substrate W into the second substrate processing apparatus SA2 (in operation Sa23), forming the second metal barrier MB2 in the trench TR using the second substrate processing apparatus SA2 (in operation Sa24), and forming the metal pattern MC to fill the trench TR (in operation Sa25). In the following description, elements, which are formed on the substrate W and the interlayer dielectric layer ILD, may indicate elements formed in the trench TR. The formation of the first metal barrier MB1 may be performed in the first substrate processing apparatus SA1. The (1-1)-th process chamber PC1-1 may be used to form the first metal barrier MB1. The first metal barrier MB1 may be formed on the interlayer dielectric layer ILD. The first metal barrier MB1 may be formed in the trench TR. The formation of the second metal barrier MB2 may be performed in the second substrate processing apparatus SA2. The second metal barrier MB2 may be formed on the first metal barrier MB1.

Referring to FIGS. 4 and 5, the substrate W and the interlayer dielectric layer ILD with the trench TR may be provided. The substrate W and the interlayer dielectric layer ILD may have thicknesses different from those illustrated. The substrate W may be formed of or include silicon (Si). However, example embodiments are not limited thereto. The interlayer dielectric layer ILD may be formed on the substrate W. The interlayer dielectric layer ILD may be formed of or include silicon oxide. The trench TR may be formed by performing an etching process on the interlayer dielectric layer ILD. The metal line MM may be formed in the trench TR (e.g., see FIG. 9). The interlayer dielectric layer ILD may include at least one of a silicon oxide layer or a silicon oxynitride layer. In an example embodiment, another semiconductor device may be disposed between the substrate W and the interlayer dielectric layer ILD. For example, a circuit layer may be formed between the substrate W and the interlayer dielectric layer ILD. The circuit layer may indicate a layer or region, on which an integrated circuit (e.g., an transistor) is formed. However, the structure of the circuit layer is not limited to this example. The circuit layer may include a transistor, a memory device, and a resistor. The transistor may be a single or combined FinFET, a nano-wire transistor, or a nano-sheet transistor. The memory device may include a random access memory (RAM) device, a read only memory (ROM) device, and a FLASH memory device. The metal line MM may be electrically connected to the circuit layer or the substrate W.

A conductive pattern EP may be placed in the interlayer dielectric layer ILD. The conductive pattern EP may have an electrically conductive property. The conductive pattern EP may be formed of or include at least one of copper (Cu), tungsten (W), cobalt (Co), ruthenium (Ru), or molybdenum (Mo). However, example embodiments are not limited thereto. The conductive pattern EP may include a plurality of interconnection lines, which are spaced apart from each other vertically or horizontally. The conductive pattern EP may include via plugs and contact plugs, which are used to connect a plurality of vertically-stacked interconnection lines. The interconnection lines may be metal lines. The contact plugs may electrically connect the interconnection lines to the substrate W. The conductive pattern EP may be provided below the trench TR. The metal line MM may be electrically connected to the circuit layer or the substrate W through the conductive pattern EP. The metal line MM may be electrically connected to the substrate W by the conductive pattern EP and the circuit layer.

Referring to FIG. 6, the first metal barrier MB1 may be formed in the trench TR. Referring to FIG. 7, the second metal barrier MB2 may be formed on the first metal barrier MB1. Referring to FIG. 8, the seed layer SL may be formed on the second metal barrier MB2. For example, the first metal barrier MB1, the second metal barrier MB2 and the seed layer SL may conform to a shape of the trench TR and may extend outside of the trench along an upper surface of the interlayer dielectric layer ILD. The seed layer SL will be described in more detail below. The disposition of the seed layer SL is not limited to this example, and the seed layer SL may be formed on the first metal barrier MB1, without the second metal barrier MB2. The first and second metal barriers MB1 and MB2 may have an amorphous structure. Amorphous structure can refer to the property of a material in which no regularity can be found in the arrangement of atoms over a long distance. In the case where the first and second metal barriers MB1 and MB2 have the amorphous structure, it may be possible to prevent a material on the first and second metal barriers MB1 and MB2 from being diffused through a grain boundary. Each of the first and second metal barriers MB1 and MB2 may be formed of or include at least one of tantalum nitride (TaN), tantalum nitride-tantalum alloy (TaN/Ta), or ruthenium-doped tantalum nitride (Ru-doped TaN). However, the materials of the first and second metal barriers MB1 and MB2 are not limited to these examples. The first metal barrier MB1 may further include another material preventing a material, which is formed on the first metal barrier MB1, from being diffused into the interlayer dielectric layer ILD. The second metal barrier MB2 may further include another material preventing a material, which is formed on the second metal barrier MB2, from being diffused into the interlayer dielectric layer ILD. For example, the first and second metal barriers MB1 and MB2 may include different compositions.

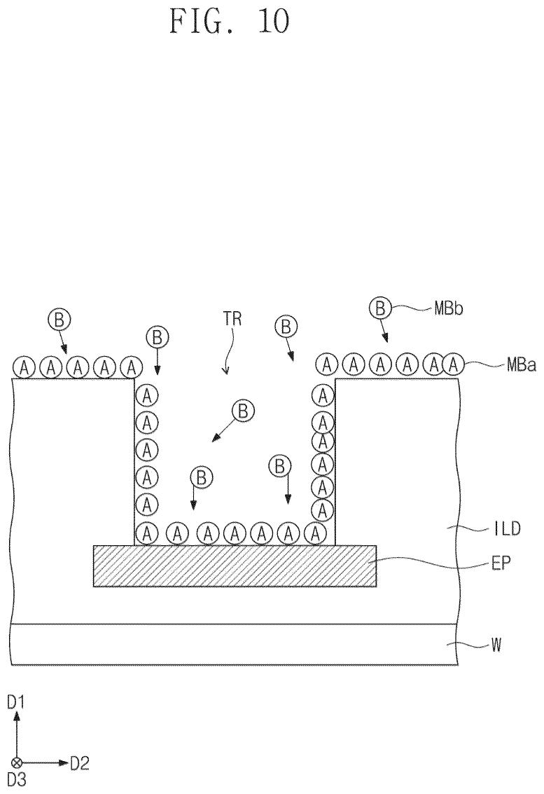

The first and second metal barriers MB1 and MB2 may be formed through different processes. For example, the first metal barrier MB1 may be formed by an atomic layer deposition (ALD) method. The second metal barrier MB2 may be formed by a physical vapor deposition (PVD) method. The ALD and PVD methods will be described in more detail below with reference to FIGS. 10, 11, 12, and 13. The first and second metal barriers MB1 and MB2 may be formed in different substrate processing apparatuses SA. Different processes may be performed in different substrate processing apparatuses SA. The first metal barrier MB1 may be formed in the first substrate processing apparatus SA1. The second metal barrier MB2 may be formed in the second substrate processing apparatus SA2. The first metal barrier MB1 may be formed by a PVD method. The second metal barrier MB2 may be formed by an ALD method. However, the formation of the first and second metal barriers MB1 and MB2 is not limited to this example.

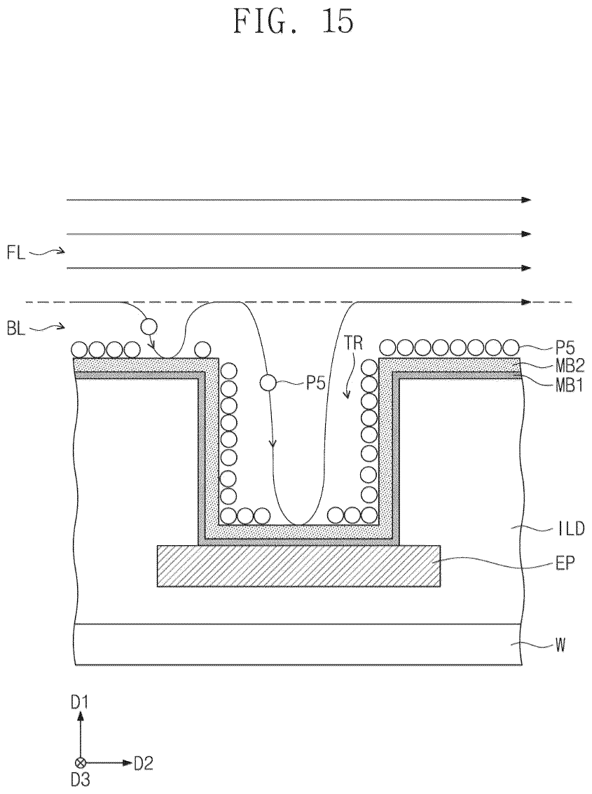

Referring to FIG. 9, the metal pattern MC may be formed to fill the trench TR. In an example embodiment, the metal pattern MC may be formed by forming a metal layer on the seed layer SL and performing a planarization process on the metal layer. The planarization process may be a chemical mechanical planarization process. The planarization process may be performed to expose the interlayer dielectric layer ILD. In this case, each of the first metal barrier MB1, the second metal barrier MB2, the seed layer SL, and the metal pattern MC may be confined within the trench TR, and as a result, the metal line MM may be formed in the trench TR. The metal line MM may include the metal pattern MC, the seed layer SL, and the first metal barrier MB1, the second metal barrier MB2, which are formed in the trench TR. However, the structure of the metal line MM is not limited to this example. The metal pattern MC may be formed on the seed layer SL. However, the position of the metal pattern MC is not limited to this example. The metal pattern MC may be formed on the first or second metal barrier MB1 or MB2, without the seed layer SL. The metal pattern MC may be formed on one metal barrier. The metal pattern MC may be formed on a liner layer LL, which will be described with reference to FIG. 15. In the following description, the metal pattern MC may be formed through the last deposition process performed to form the metal line MM. The metal pattern MC may be formed on any combination of the metal barriers, the liner layer LL, and the seed layer SL. The metal pattern MC may be formed of or include at least one of copper (Cu), aluminum (Al), tungsten (W), ruthenium (Ru), molybdenum (Mo), or titanium (Ti).

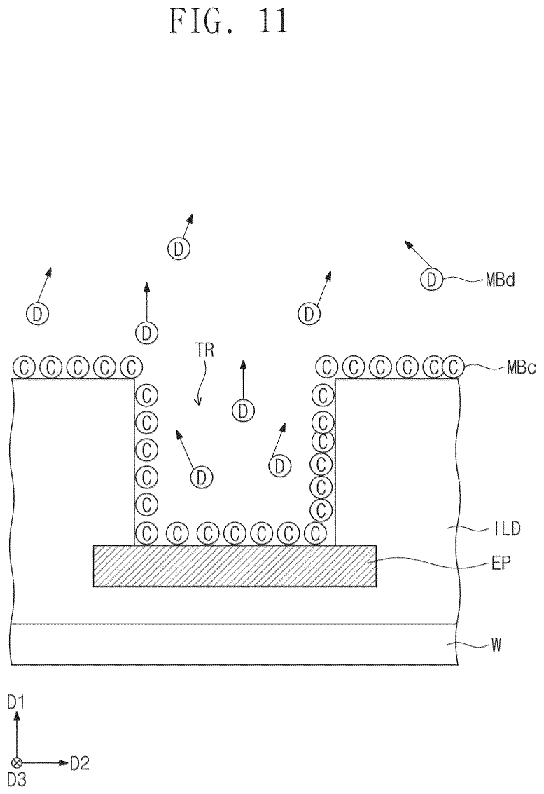

FIGS. 10 and 11 are sectional views illustrating an atomic layer deposition (ALD) process, which is performed on the substrate W and the interlayer dielectric layer ILD, according to an example embodiment.

Referring to FIGS. 10 and 11, an ALD method may be performed to form the first metal barrier MB1 on the substrate W, the interlayer dielectric layer ILD and the conductive pattern EP. In the (1-1)-th process chamber PC1-1, the first metal barrier MB1 may be formed in the trench TR. A precursor MBa may be injected into the (1-1)-th process chamber PC1-1. The precursor MBa may be deposited on the interlayer dielectric layer ILD and the conductive pattern EP. The precursor MBa may be chemically adsorbed on a surface of the interlayer dielectric layer ILD and a surface of the conductive pattern EP. If the precursor MBa and the interlayer dielectric layer ILD, and the precursor MBa and the conductive pattern EP, sufficiently react with each other on a surface of the interlayer dielectric layer ILD and a surface of the conductive pattern EP through a self-saturation reaction, the deposition of the precursor MBa may be controlled to stop. The precursor MBa, which is not adsorbed on the interlayer dielectric layer ILD and the conductive pattern EP, may be removed, and then, a reactant MBb may be injected into the (1-1)-th process chamber PC1-1. A product MBc may be formed as a result of a chemical reaction between the reactant MBb and the precursor MBa. The product MBc may be aggregated to form a thin film. A residue MBd, which is left after the reaction between the reactant MBb and the precursor MBa, may be exhausted from the (1-1)-th process chamber PC1-1 to the outside. In the following description, an ALD method may be performed in a manner similar to the ALD method described with reference to FIGS. 10 and 11.

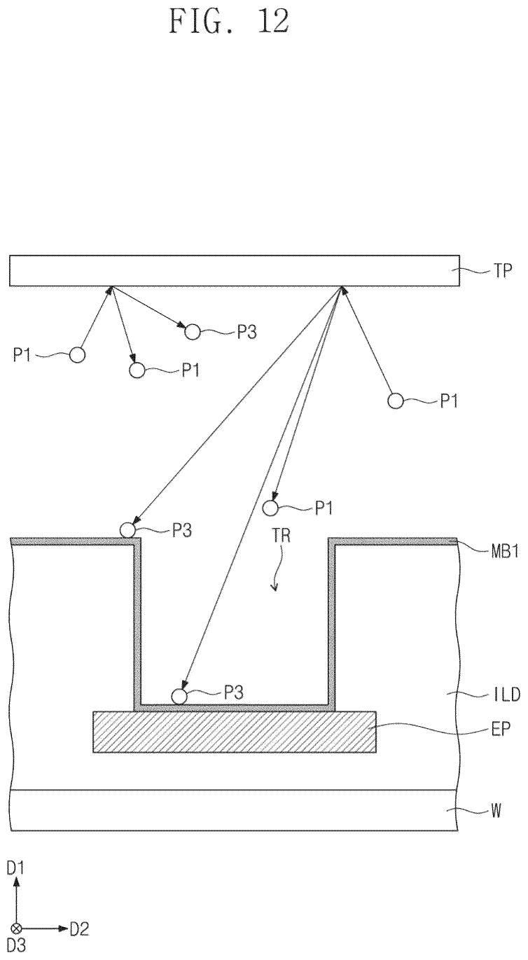

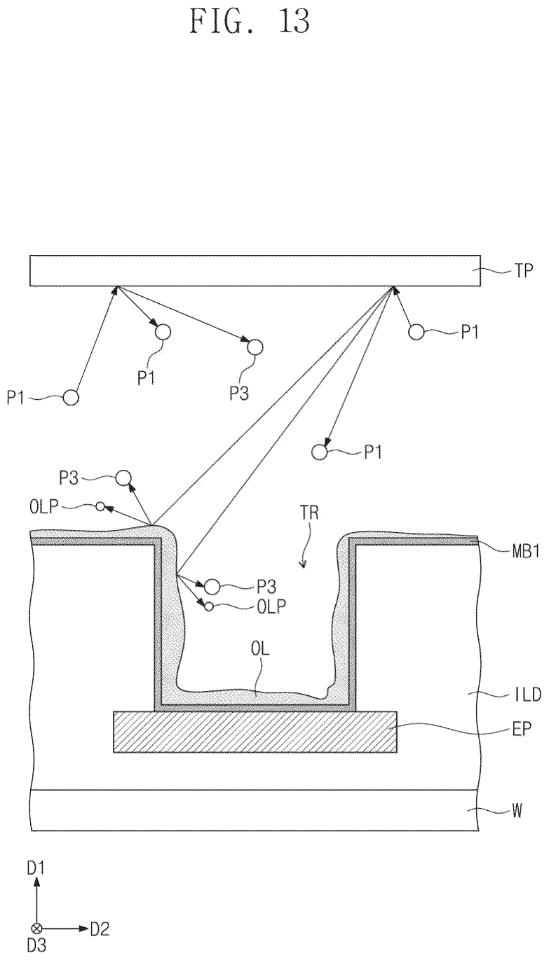

FIGS. 12 and 13 are sectional views illustrating a physical vapor deposition (PVD) process, which is performed on the substrate W and the interlayer dielectric layer ILD, according to an example embodiment. For example, the PVD processes shown in FIGS. 12 and 13 may be performed in different substrate processing apparatuses SA.

Referring to FIG. 12, a PVD process may be performed on a structure including the substrate W, the interlayer dielectric layer ILD and the conductive pattern EP. For example, the PVD process on the substrate W and the interlayer dielectric layer ILD (and the conductive pattern EP) may be performed in the (2-1)-th process chamber PC2-1. An inert gas PI may be injected into the (2-1)-th process chamber PC2-1, in which the substrate W is placed. The inert gas PI may be in a plasma state. When the inert gas PI collides with a target plate TP, a target plate particle P3 may be ejected from the target plate TP. The inert gas PI can bounce off after colliding with the target plate TP. However, the inert gas PI can stick to the target plate TP without being bounced off after colliding with the target plate TP. The target plate particle P3 may be deposited on the interlayer dielectric layer ILD. The ejection of the target plate particle P3, which occurs as a result of the collision between the inert gas P1 and the target plate TP, may be referred to as a ‘sputtering process’. The sputtered target plate particle P3 may be deposited on the first metal barrier MB1.

FIG. 13 illustrates a PVD process, which is performed on the substrate W and the interlayer dielectric layer ILD covered with an oxide layer OL. For example, the PVD process in the following description, as the substrate W is transferred between the substrate processing apparatuses SA, it may be understood that the substrate W and the interlayer dielectric layer ILD are exposed to a non-vacuum environment. In an example embodiment, when the substrate W is transferred from one substrate processing apparatus SA to another substrate processing apparatus SA, the substrate W and the interlayer dielectric layer ILD may be exposed to the air. As noted above, the PVD processes shown in FIGS. 12 and 13 may be performed in different substrate processing apparatuses SA. In the case where the substrate W is exposed to a non-vacuum environment, the oxide layer OL may be formed on the interlayer dielectric layer ILD. When the substrate W is transferred from the first substrate processing apparatus SA1 to the second substrate processing apparatus SA2, the substrate W and the interlayer dielectric layer ILD may be exposed to a non-vacuum environment. When the substrate W is transferred from the first substrate processing apparatus SAI which performed the PVD process shown in FIG. 12 to the second substrate processing apparatus SA2 which performs the PVD process shown in FIG. 13, the substrate W and the interlayer dielectric layer ILD may be exposed to the air. Thus, the oxide layer OL may be formed on the first metal barrier MB1. If the target plate particle P3 collides with the oxide layer OL, due to a high energy of the sputtered target plate particle P3, an oxide layer particle OLP may be detached from the oxide layer OL. As a result, the oxide layer OL may be removed by the target plate particle P3. The oxide layer OL of the metal line MM may be removed by the sputtering method of the PVD process. In the following description, a PVD process and a sputtering process may be performed in a manner similar to those described with reference to FIGS. 12 and 13.

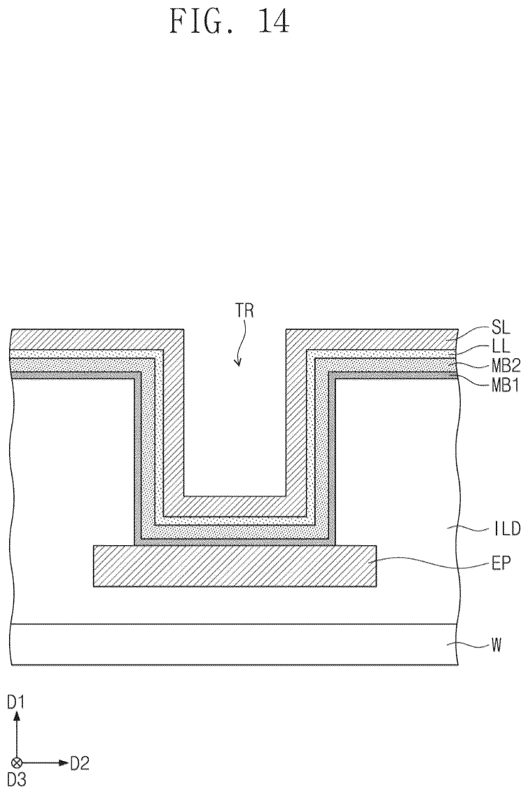

FIG. 14 is a sectional view illustrating the substrate W and the interlayer dielectric layer ILD, on which the first metal barrier MB1, the second metal barrier MB2, the liner layer LL, and the seed layer SL are formed, according to an example embodiment, and FIG. 15 is a sectional view illustrating a chemical vapor deposition (CVD) process, which is performed on the substrate W and the interlayer dielectric layer ILD, according to an example embodiment.

The seed layer SL may aid in conducting electrons, when the metal pattern MC is formed in the trench TR using an electro-plating process. A metal layer may be grown on the seed layer SL. The metal pattern MC may be formed on the seed layer SL. The metal pattern MC may be formed of or include at least one of copper (Cu), aluminum (Al), tungsten (W), ruthenium (Ru), molybdenum (Mo), or titanium (Ti). Electrons may be conducted through the metal pattern MC on the seed layer SL. If there is no conduction of electrons in the electro-plating process, an electrochemical reaction may not occur, and in this case, the metal pattern MC may not be formed. In the case where there is a problem in the electrochemical reaction, the metal pattern MC may be formed to have a poor step-coverage property, and this may lead to a failure in a fabricated semiconductor device. Because the seed layer SL may be used as a nuclear in nucleation, the seed layer SL may be used to grow a crystalline structure of the metal pattern MC in the electro-plating process. A property of the metal pattern MC may depend on a thickness, a crystalline structure, and a gain size of the seed layer SL. The seed layer SL may be formed of or include at least one of copper (Cu), titanium (Ti), ruthenium (Ru), molybdenum (Mo), tungsten (W), or copper alloy (Cu Alloy). The seed layer SL may be formed by a PVD method. However, a method of forming the seed layer SL is not limited to this example.

Referring to FIG. 14, the liner layer LL may be used to form the seed layer SL to a uniform thickness. The liner layer LL may be configured to provide an environment allowing the seed layer SL to be uniformly formed. The seed layer SL may be uniformly formed by the liner layer LL. The liner layer LL may be formed of or include cobalt (Co), ruthenium (Ru), or ruthenium-cobalt alloy (Ru—Co Alloy). The liner layer LL may be formed by a chemical vapor deposition (CVD) method. Referring to FIG. 15, the CVD method may be performed using a reactive gas P5. In the (2-2)-th process chamber PC2-2, a liner layer may be formed in the trench TR. The reactive gas P5 may be injected into the (2-2)-th process chamber PC2-2. The reactive gas P5 may form a laminar flow FL. A boundary layer BL, in which a velocity of the reactive gas P5 relative to the interlayer dielectric layer ILD or the metal line MM (e.g., see FIG. 9) is zero, may be formed below the laminar flow FL. The reactive gas P5 may be reacted with the interlayer dielectric layer ILD or the metal line MM. If a concentration of the reactive gas P5 in the boundary layer BL is lowered, the reactive gas P5 may be diffused from the laminar flow FL into the boundary layer BL. The interlayer dielectric layer ILD or the metal line MM may react with the reactive gas P5 of the boundary layer BL to form a thin film. To react the reactive gas P5 with the interlayer dielectric layer ILD or the metal line MM, the (2-2)-th process chamber PC2-2 may be heated or may be used to generate plasma. However, the method of forming the liner layer LL is not limited to this example. The CVD process may be a process of forming a new thin film through a reaction between the reactive gas P5 and the interlayer dielectric layer ILD or the metal line MM, without forming the laminar flow FL and the boundary layer BL of the reactive gas P5. In the following description, a CVD method may be performed in a manner similar to the CVD method described with reference to FIG. 15. The liner layer LL may be formed by a PVD or ALD method.

One of the first and second metal barriers MB1 and MB2 may not be formed in the trench TR. In an example embodiment, the first substrate processing apparatus SAI may be used to form only the first metal barrier MB1 in the trench TR. In the first substrate processing apparatus SA1, the first metal barrier MB1 may be formed by a PVD method. However, the method of forming the first metal barrier MB1 is not limited to this example. When the substrate W is transferred from the first substrate processing apparatus SAI to the second substrate processing apparatus SA2, the oxide layer OL may be formed on the substrate W and the interlayer dielectric layer ILD. The oxide layer OL of the metal line MM, which is formed when the substrate W is exposed to the air or the non-vacuum environment, may be removed by a sputtering process, which is performed in the second substrate processing apparatus SA2. In the second substrate processing apparatus SA2, the seed layer SL may be formed on the first metal barrier MB1. The liner layer LL may be formed on the first metal barrier MB1, in the first substrate processing apparatus SA1, before the substrate W is exposed to the non-vacuum environment.

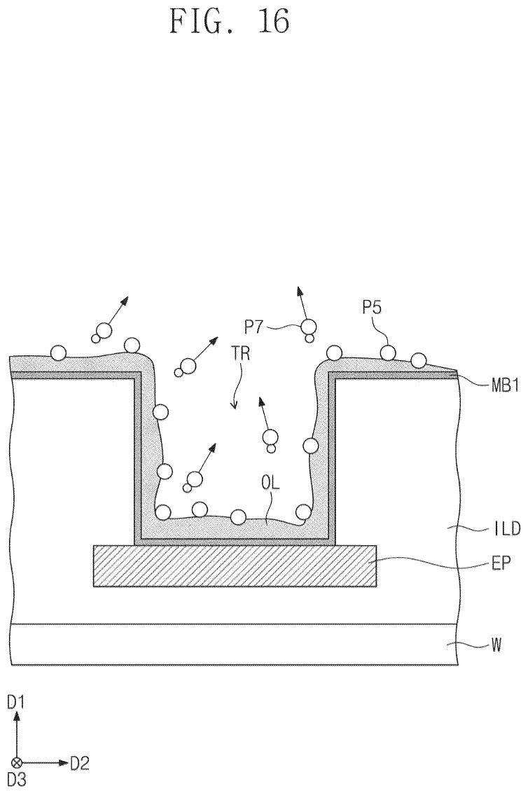

FIG. 16 is a sectional view illustrating a chemical reaction process, which is performed on the substrate W and the interlayer dielectric layer ILD, according to an example embodiment.

In the first substrate processing apparatus SA1, the first metal barrier MB1 may be formed using an ALD method. However, the method of forming the first metal barrier MB1 is not limited to this example. For example, the first metal barrier MB1 may be formed by a CVD and PVD method. The first metal barrier MB1 may be formed in the (1-1)-th process chamber PC1-1. The substrate W may be unloaded from the first substrate processing apparatus SAI and may be exposed to a non-vacuum environment. Thus, an oxide layer OL may be formed on the first metal barrier MB1. The substrate W may be loaded in the second substrate processing apparatus SA2. The substrate W may be loaded in the (2-1)-th process chamber PC2-1. FIG. 16 illustrates a pre-cleaning process, which is performed on the substrate W and the interlayer dielectric layer ILD in the (2-1)-th process chamber PC2-1. The oxide layer OL and/or a contamination material on the interlayer dielectric layer ILD may be removed by the pre-cleaning process. For the pre-cleaning process, the reactive gas P5 may be injected into the (2-1)-th process chamber PC2-1. The oxide layer OL may be removed through a reaction between the reactive gas P5 and oxygen atoms of the oxide layer OL. A partial pressure of the reactive gas P5 may be increased to increase the reactivity between the reactive gas P5 and the oxide layer OL. An internal temperature of the (2-1)-th process chamber PC2-1 may be increased to increase the reactivity between the reactive gas P5 and the oxide layer OL. The reactive gas P5 may include hydrogen (H₂) radicals. However, the kind of the reactive gas P5 is not limited to this example. The reactive gas P5 may include various other materials, which can be reacted with the oxide layer OL.

Hereinafter, various processes, which can be performed in the second substrate processing apparatus SA2 after the removal of the oxide layer OL, will be described. Such processes are not limited to examples to be described below and include other processes. After the pre-cleaning process, the second substrate processing apparatus SA2 may be used to form the seed layer SL. Before the formation of the seed layer SL, the second substrate processing apparatus SA2 may be used to form the liner layer LL on the first metal barrier MB1. The liner layer LL may be formed by a CVD method. However, in an example embodiment, the formation of the seed layer SL may be performed in another substrate processing apparatus SA. For example, after the pre-cleaning process performed in the second substrate processing apparatus SA2, the substrate W may be transferred from the second substrate processing apparatus SA2 to the third substrate processing apparatus SA3 of a vacuum state. In the third substrate processing apparatus SA3, the second metal barrier MB2 may be formed in the trench TR. The formation of the second metal barrier MB2 may be performed by a PVD method (e.g., see FIG. 12). The oxide layer OL of the metal line MM, which is formed when the substrate W is transferred from the second substrate processing apparatus SA2 to the third substrate processing apparatus SA3, may be removed through a sputtering process (e.g., see FIG. 13).

Before forming the seed layer SL in the third substrate processing apparatus SA3, the liner layer LL, which is used to form the seed layer SL to a uniform thickness, may be formed in the trench TR, in the third substrate processing apparatus SA3.

The second metal barrier MB2, instead of the liner layer LL, may be formed in the second substrate processing apparatus SA2, before forming the seed layer SL in the trench TR. That is, the pre-cleaning process may be performed in the second substrate processing apparatus SA2, after the formation of the first metal barrier MB1 in the first substrate processing apparatus SA1. The second metal barrier MB2 may be formed in the second substrate processing apparatus SA2 after the pre-cleaning process. The second metal barrier MB2 may be formed by a method different from that for the first metal barrier MB1. For example, the second metal barrier MB2 may be formed by a PVD or CVD method. After the formation of the second metal barrier MB2 in the second substrate processing apparatus SA2, the seed layer SL may be formed on the second metal barrier MB2. After the formation of the second metal barrier MB2 in the second substrate processing apparatus SA2, the liner layer LL may be formed on the second metal barrier MB2, and the seed layer SL may be formed thereon. The first metal barrier MB1 may be formed by a PVD method. However, the method of forming the first metal barrier MB1 is not limited to this example. The first metal barrier MB1 may be formed using a CVD method.

After the first metal barrier MB1 is formed in the trench TR in the first substrate processing apparatus SA1, the substrate W may be transferred to the second substrate processing apparatus SA2. The pre-cleaning process may be performed in the second substrate processing apparatus SA2. After the pre-cleaning process, the seed layer SL may be formed on the liner layer LL, in the second substrate processing apparatus SA2. Before the substrate W is transferred to the second substrate processing apparatus SA2, the liner layer LL may be formed on the first metal barrier MB1, in the first substrate processing apparatus SA1.

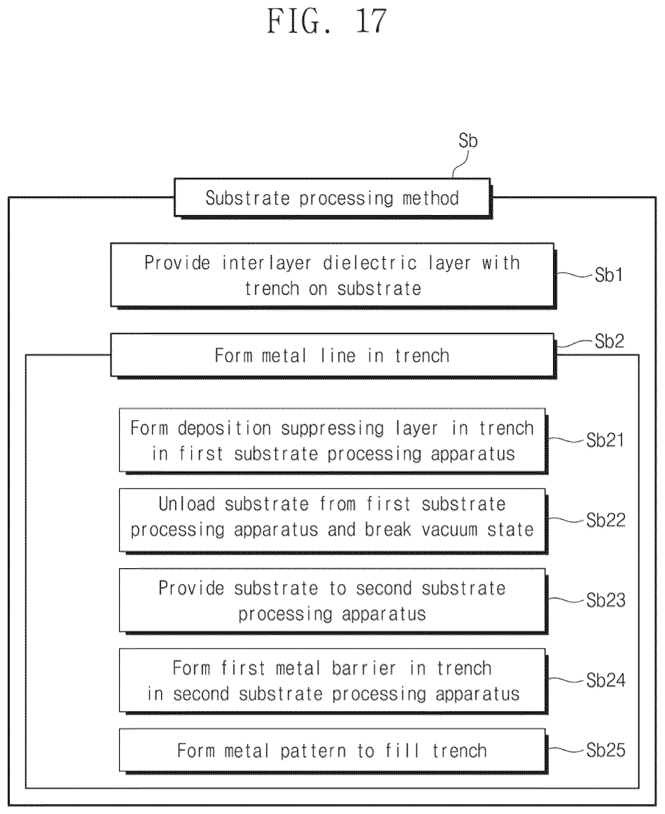

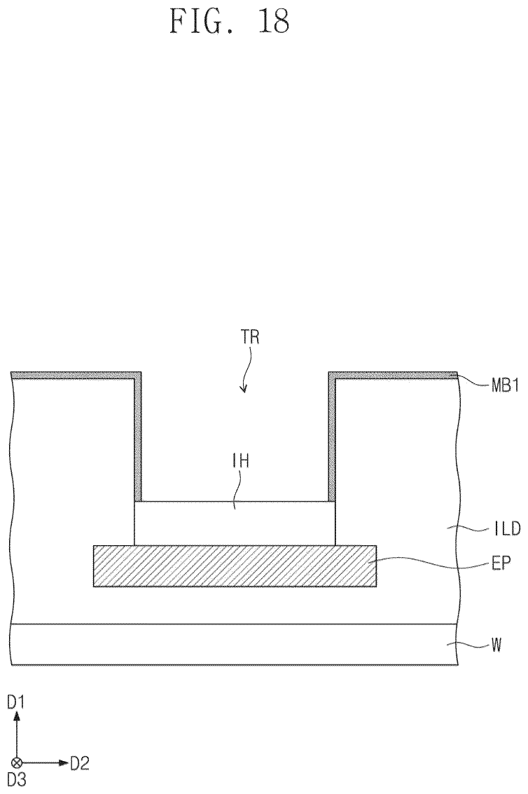

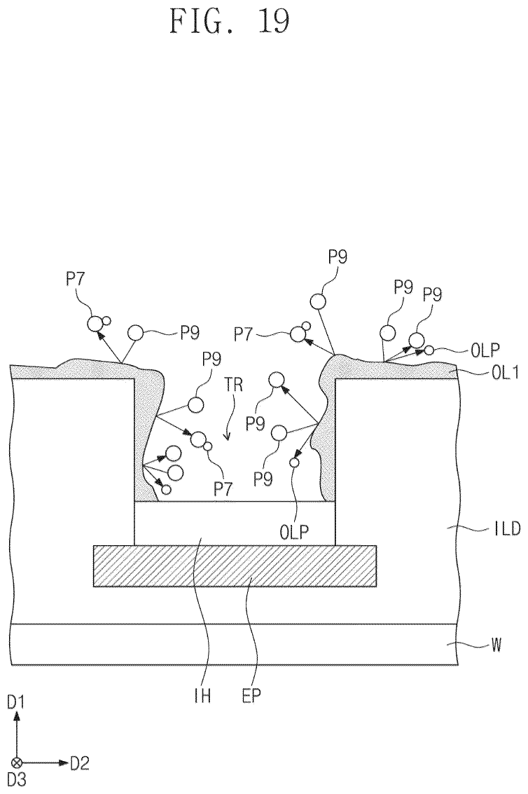

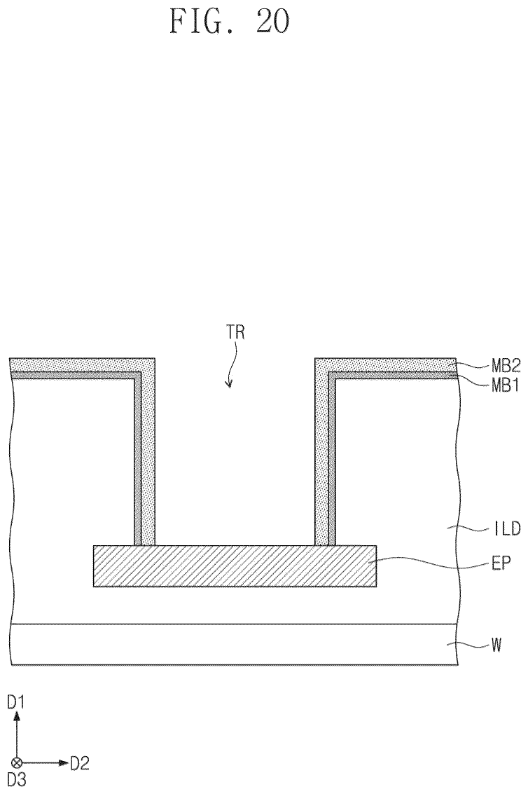

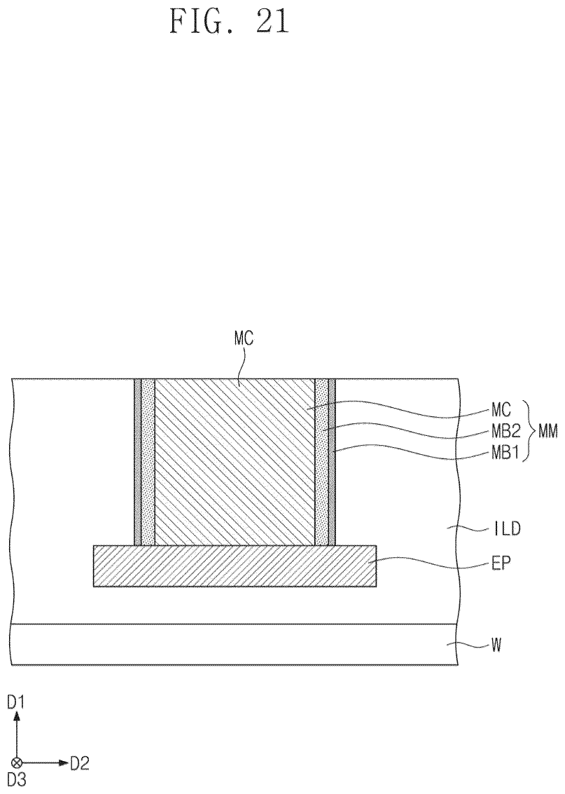

FIG. 17 is a flow chart illustrating a method Sb of fabricating a semiconductor device according to an example embodiment, FIG. 18 is a sectional view illustrating the substrate W and the interlayer dielectric layer ILD, on which a deposition suppressing layer IH and the first metal barrier MB1 are formed, according to an example embodiment, FIG. 19 is a sectional view illustrating a sputtering process, which is performed to remove the oxide layer OL from the substrate W and the interlayer dielectric layer ILD, according to an example embodiment, FIG. 20 is a sectional view illustrating the substrate W and the interlayer dielectric layer ILD, on which the first and second metal barriers MB1 and MB2 are formed, according to an example embodiment, and FIG. 21 is a sectional view illustrating the substrate W and the interlayer dielectric layer ILD, on which the metal pattern MC on the second metal barrier MB2 is formed, according to an example embodiment.

Referring to FIG. 17, the fabrication method Sb may include providing the interlayer dielectric layer ILD with the trench TR on the substrate W (in operation Sb1) and forming the metal line MM in the trench TR (in operation Sb2). The formation of the metal line MM (in operation Sb2) may include forming the deposition suppressing layer IH in the first substrate processing apparatus SA1 (in operation Sb21), unloading the substrate W from the first substrate processing apparatus SA1 to break a vacuum state of the first substrate processing apparatus SA1 (in operation Sb22), transferring the substrate W in the second substrate processing apparatus SA2 (in operation Sb23), forming the first metal barrier MB1 using the second substrate processing apparatus SA2 (in operation Sb24), and forming the metal pattern MC to fill the trench TR (in operation Sb25). A pre-treatment process may include removing a contamination material or the oxide layer OL on the substrate W and the interlayer dielectric layer ILD. The pre-treatment process may include forming the deposition suppressing layer IH in the trench TR. The pre-treatment process may facilitate the nucleation of a layer, which is formed on the interlayer dielectric layer ILD, and may enhance the uniformity in thickness of the layer. A density of the layer, which is provided on the substrate W, may be increased by the pre-treatment process.

Referring to FIG. 18, the interlayer dielectric layer ILD, on which the deposition suppressing layer IH and the first metal barrier MB1 are formed, may be provided. The first substrate processing apparatus SA1 may be used to form the deposition suppressing layer IH in the trench TR. The substrate W may be unloaded from the first substrate processing apparatus SA1 and may be exposed to a non-vacuum environment. The substrate W may be loaded in the second substrate processing apparatus SA2. The second substrate processing apparatus SA2 may be used to form the first metal barrier MB1. The deposition suppressing layer IH may prevent other material from being deposited on the interlayer dielectric layer ILD. The deposition suppressing layer IH may suppress the first and second metal barriers MB1 and MB2 from being formed on a top surface of the interlayer dielectric layer ILD. The deposition suppressing layer IH may suppress the first and second metal barriers MB1 and MB2 from being formed on a bottom surface of the trench TR. The deposition suppressing layer IH may include a polymer material. The deposition suppressing layer IH may contain carbon (C). The first metal barrier MB1 may be formed using an ALD method. However, the method of forming the first metal barrier MB1 is not limited to this example. The first metal barrier MB1 may be formed using a PVD or CVD method. The first metal barrier MB1 may be formed using a plasma-enhanced atomic layer deposition (PEALD) method or a thermal ALD method. The first metal barrier MB1 may be formed using plasma.

Referring to FIG. 19, the oxide layer OL, which is formed on the substrate W and the interlayer dielectric layer ILD, may be removed by a plasma particle P9. Plasma may be an ionized gas containing free electrons, ions, radicals, and neutral particles. The plasma particle P9 may be one of the free electrons, the ions, the radicals, and the neutral particles. Due to high reactivity of the radicals, the radicals may cause chemical reaction with the substrate W. The radicals may react with a layer, which is formed on the substrate W and the interlayer dielectric layer ILD. The ions may have an electrical property. The ions may be sputtered on the substrate W by accelerating the ions with an electric field. When the substrate W is transferred from the first substrate processing apparatus SA1 to the second substrate processing apparatus SA2, a first oxide layer OL1 may be formed on the substrate W and the interlayer dielectric layer ILD. Referring to FIG. 19, the substrate W and the interlayer dielectric layer ILD, on which the first oxide layer OL1 is formed, may be provided. A portion of the first oxide layer OL1 may be formed on the deposition suppressing layer IH. The first oxide layer OL1 may be removed through a physical and chemical reaction of the plasma particle P9. The first oxide layer OL1 may be removed through a sputtering of the ions. The first oxide layer OL1 may be removed through a chemical reaction between the radicals and the first oxide layer OL1. The oxide layer compound P7 may be formed when the plasma particles P9 collide with the first oxide layer OL1. As the oxide layer compound P7 is formed from the first oxide layer OL1, the first oxide layer OL1 may be removed. The deposition suppressing layer IH, along with the first oxide layer OL1, may be removed by the plasma particle P9.

Referring to FIG. 20, the substrate W and the interlayer dielectric layer ILD, on which the second metal barrier MB2 on the first metal barrier MB1 are formed, may be provided. Due to the deposition suppressing layer IH, it may be possible to prevent or suppress the oxide layer OL and the first and second metal barriers MB1 and MB2 from being formed in a specific region of the trench TR. By using the deposition suppressing layer IH, it may be possible to prevent any other material from being formed below the metal pattern MC.

Referring to FIG. 21, the metal line MM may be formed in the trench TR. The metal pattern MC may be formed on the first and second metal barriers MB1 and MB2. However, the position of the metal pattern MC is not limited to this example. For example, the metal pattern MC may be formed on the combination of the first metal barrier MB1, the second metal barrier MB2, the liner layer LL, and the seed layer SL. Only one metal barrier may be formed below the metal pattern MC. A bottom surface of the metal pattern MC may be directly connected to the interlayer dielectric layer ILD.

Hereinafter, various processes, which can be performed after forming the deposition suppressing layer IH in the first substrate processing apparatus SA1 and forming the first metal barrier MB1 in the second substrate processing apparatus SA2, will be described. Such processes are not limited to examples to be described below and include other processes. The substrate W may be transferred from the second substrate processing apparatus SA2 to the third substrate processing apparatus SA3 of a vacuum state. When the substrate W is transferred from the second substrate processing apparatus SA2 to the third substrate processing apparatus SA3, the substrate W may be exposed to a non-vacuum environment and a second oxide layer of the metal line MM may therefore be formed. The third substrate processing apparatus SA3 may be used to form the seed layer SL in the trench TR. The seed layer SL may be formed by a PVD method. The second oxide layer may be removed when a sputtering process using the PVD method is performed.

After the substrate W is transferred to the third substrate processing apparatus SA3, the second metal barrier MB2 may be formed in the trench TR, before the formation of the seed layer SL. The second metal barrier MB2 may be formed by a PVD method. The second oxide layer may be removed by a sputtering process, when the second metal barrier MB2 is formed. The liner layer LL may be formed on the second metal barrier MB2, after the formation of the second metal barrier MB2. However, the removal of the second oxide layer is not limited to this example.

After the substrate W is transferred to the third substrate processing apparatus SA3, the liner layer LL, instead of the second metal barrier MB2, may be formed in the trench TR. The liner layer LL may be formed by a CVD method. In the third substrate processing apparatus SA3, the oxide layer OL may be removed through a chemical reaction between the reactive gas P5 and the oxide layer OL. The liner layer LL may be formed by a plasma-enhanced chemical vapor deposition (PECVD) method. The PECVD method may be performed using the plasma particle P9. In the third substrate processing apparatus SA3, the second oxide layer may be removed through a reaction between the plasma particle P9 and the second oxide layer, before the formation of the liner layer LL. In the third substrate processing apparatus SA3, the second oxide layer may be removed through a plasma-using physical and chemical reaction. In the third substrate processing apparatus SA3, the second oxide layer may be removed by a plasma-using sputtering process and a chemical reaction process.

After the substrate W is transferred to the third substrate processing apparatus SA3, a post-treatment process may be performed on the substrate W and the interlayer dielectric layer ILD, in the third substrate processing apparatus SA3. The post-treatment process may include removing the deposition suppressing layer IH using a sputtering process or a plasma-using chemical reaction process and removing the second oxide layer or a contamination material from the substrate W and the interlayer dielectric layer ILD. The second oxide layer or the contamination material on the substrate W and the interlayer dielectric layer ILD may be removed through a sputtering process or a plasma-using chemical reaction process. The process of removing the deposition suppressing layer IH and the second oxide layer using the plasma may include at least one of a chemical reaction process or a sputtering process. The deposition suppressing layer IH and the second oxide layer may be removed once again through the post-treatment process. After the post-treatment process in the third substrate processing apparatus SA3, the third substrate processing apparatus SA3 may be used to form the seed layer SL in the trench TR. However, the liner layer LL may be formed on the interlayer dielectric layer ILD, on which the post-treatment process is performed, in the third substrate processing apparatus SA3, before the forming of the seed layer SL. In this regard, the liner layer LL may be formed on the first metal barrier MB1. The liner layer LL may be formed using a CVD method.

After the substrate W is transferred to the third substrate processing apparatus SA3, a pre-cleaning process may be performed on the substrate W and the interlayer dielectric layer ILD in the third substrate processing apparatus SA3. In an example embodiment, the pre-cleaning process may be performed in a (3-1)-th process chamber PC3-1 (e.g., see FIG. 2) of the third substrate processing apparatus SA3. The reactive gas P5 may be injected into the (3-1)-th process chamber PC3-1. The reactive gas P5 may be injected into the third substrate processing apparatus SA3. In the third substrate processing apparatus SA3, the second oxide layer may be chemically reacted with the reactive gas P5, and as a result, the second oxide layer may be removed. After the removal of the second oxide layer, a pre-cleaning process may be performed in the third substrate processing apparatus SA3. The substrate W may be transferred from the third substrate processing apparatus SA3 to the fourth substrate processing apparatus. When the substrate W is transferred from the third substrate processing apparatus SA3 to the fourth substrate processing apparatus, the substrate W may be exposed to a non-vacuum environment. When the substrate W is transferred from the third substrate processing apparatus SA3 to the fourth substrate processing apparatus, a third oxide layer of the metal line MM may be formed due to the non-vacuum environment.

The fourth substrate processing apparatus may be used to form the second metal barrier MB2 in the trench TR. The second metal barrier MB2 may be formed by a PVD method. In the fourth substrate processing apparatus, the third oxide layer may be removed by a sputtering process. However, a method of removing the third oxide layer using the fourth substrate processing apparatus is not limited to this example. The fourth substrate processing apparatus may be used to form the liner layer LL in the trench TR. The liner layer LL may be formed through a CVD method. In the fourth substrate processing apparatus, the third oxide layer may react with the reactive gas P5 and may be removed. The liner layer LL may be formed using a CVD method. The liner layer LL may be formed through a PECVD method using plasma. The third oxide layer may be removed by a physical and chemical reaction of plasma. The seed layer SL may be formed in the trench TR, after the third oxide layer is removed in the fourth substrate processing apparatus.

In a method of fabricating a semiconductor device according to an example embodiment, one substrate processing system may include a plurality of substrate processing apparatuses. That is, the substrate processing system may be divided into a plurality of substrate processing apparatuses. In an example embodiment, two or more substrate processing apparatuses may be provided. Because the substrate processing system includes a plurality of substrate processing apparatuses, it may be possible to improve the efficiency in space utilization. It may be possible to place the substrate processing apparatus within a small region. The substrate processing apparatus may occupy a space that is smaller than a space required to dispose a plurality of substrate processing apparatuses simultaneously.

In a method of fabricating a semiconductor device according to an example embodiment, it may be possible to improve the efficiency in the semiconductor fabrication process. In the case where the substrate processing apparatuses are all connected and cannot be separated, the entire substrate processing system cannot be utilized when one of process chambers malfunctions. By contrast, according to an example embodiment, because the substrate processing system includes a plurality of separated substrate processing apparatuses, even when one of the process chambers malfunctions, remaining ones of the process chambers may be utilized, and this may make it possible to improve the efficiency in the fabrication process.

In a method of fabricating a semiconductor device according to an example embodiment, because substrate processing apparatuses different from each other are provided, it may be possible to easily manage the substrate processing apparatus. In the case where the substrate processing apparatuses are all connected and cannot be separated, it may be necessary to replace the entire of the substrate processing apparatus, even when it is necessary to change only one of process chambers. For example, it is necessary to replace a process chamber, which is normally operated, with a new one. By contrast, in the case where the substrate processing system includes a plurality of substrate processing apparatuses, when one of the substrate processing apparatuses needs to be replaced or repaired, the remaining substrate processing apparatuses can be used without interruption for replacement or repair. Furthermore, in this case, the substrate processing apparatuses may not be managed by just one manufacturer, and they may be separately managed by different manufacturers.

In a method of fabricating a semiconductor device according to an example embodiment, it may be possible to remove an oxide layer, which is formed when a substrate is transferred between substrate processing apparatuses, using various methods. The oxide layer may be removed by a sputtering process, when a PVD process is performed. The oxide layer may be removed from the substrate by colliding a target plate particle or an inert gas with the oxide layer. The oxide layer may be removed when the ALD process is performed. The ALD process may be performed using plasma. The plasma may be used to remove the oxide layer, through physical and chemical reactions with the oxide layer. The oxide layer may be removed through a chemical reaction between plasma particles and the oxide layer. The oxide layer may be removed through physical reaction between the oxide layer and ions of the plasma particles. The ions may remove the oxide layer through collision with the oxide layer. The ions may be used to remove the oxide layer through a sputtering process. The oxide layer may be removed, when a CVD process is performed. The oxide layer may be removed by a chemical reaction between a reactive gas, which is used in the CVD process, and the oxide layer. In the case where plasma is used in the CVD process, the oxide layer may physically and chemically react with the plasma and may be removed. The oxide layer may be removed through a sputtering and chemical reaction with the plasma. The oxide layer may be removed through a pre-cleaning process. In the pre-cleaning process, the oxide layer may be removed through a reaction between the reactive gas and the oxide layer. The oxide layer may be removed through a post-treatment process. Because a deposition suppressing layer is removed in the post-treatment process, the oxide layer may also be removed. In the post-treatment process, the oxide layer may be removed by a sputtering process and a chemical reaction process.

In a method of fabricating a semiconductor device according to an example embodiment, an oxide layer of a metal line which is formed when a substrate is transferred in a non-vacuum environment may be removed.

In a method of fabricating a semiconductor device according to an example embodiment, an oxide layer of a metal line may be removed using a sputtering process.

In a method of fabricating a semiconductor device according to an example embodiment, an oxide layer of a metal line may be removed through a chemical reaction process using a reactive gas or plasma.

In a method of fabricating a semiconductor device according to an example embodiment, a plurality of substrate processing apparatuses may be used to increase the efficiency in space utilization.

In a method of fabricating a semiconductor device according to an example embodiment, a plurality of substrate processing apparatuses may be used to diversify the kind of a process chamber and increase the efficiency of the fabrication process.

One or more substrate processing apparatuses consistent with example embodiments may include one or more processors and one or more memories. For example, each of the one or more memories may be a non-transitory computer readable medium.

While aspects of example embodiments have been particularly shown and described, it will be understood by one of ordinary skill in the art that variations in form and detail may be made therein without departing from the spirit and scope of the attached claims.

What is claimed is:

1. A method of fabricating a semiconductor device, comprising:
providing an interlayer dielectric layer with a trench on a substrate in a first substrate processing apparatus in a vacuum state;
forming a first metal barrier in the trench while the substrate is in the first substrate processing apparatus;
unloading the substrate from the first substrate processing apparatus and exposing the substrate to a non-vacuum environment;
providing the substrate in a second substrate processing apparatus of a vacuum state;
forming a second metal barrier in the trench in the second substrate processing apparatus; and
forming a metal pattern to fill the trench.

2. The method of claim 1, further comprising forming a liner layer on the second metal barrier in the second substrate processing apparatus,
wherein the liner layer comprises cobalt (Co), ruthenium (Ru), or ruthenium-cobalt alloy (Ru—Co Alloy).

3. The method of claim 2, further comprising forming a seed layer on the liner layer,
wherein each of the first and second metal barriers comprises one of tantalum nitride (TaN), tantalum nitride-tantalum alloy (TaN/Ta), or ruthenium-doped tantalum nitride (Ru-doped TaN).

4. The method of claim 1, wherein further comprising forming a seed layer on the second metal barrier in the second substrate processing apparatus,
wherein the seed layer comprises at least one of copper (Cu), titanium (Ti), ruthenium (Ru), molybdenum (Mo), tungsten (W), or copper alloy (Cu Alloy).

5. The method of claim 1, wherein further comprising:
providing the substrate with the first metal barrier in a third substrate processing apparatus in a vacuum state;
performing a pre-cleaning process on the substrate in the third substrate processing apparatus; and
unloading the substrate from the third substrate processing apparatus and exposing the substrate to a non-vacuum environment.

6. The method of claim 5, further comprising forming a seed layer on the second metal barrier, after forming the second metal barrier on the substrate.

7. The method of claim 6, further comprising forming a liner layer on the substrate, before forming the seed layer on the substrate in the second substrate processing apparatus.

8. The method of claim 1, further comprising performing a pre-cleaning process on the substrate in the second substrate processing apparatus, before forming the second metal barrier on the substrate.

9. The method of claim 8, further comprising forming a seed layer on the second metal barrier in the second substrate processing apparatus.

10. The method of claim 9, further comprising forming a liner layer on the second metal barrier, before forming the seed layer on the substrate,
wherein the liner layer comprises cobalt (Co), ruthenium (Ru), or ruthenium-cobalt alloy (Ru—Co Alloy).

11. The method of claim 1, further comprising, before forming the first metal barrier on the substrate in the first substrate processing apparatus:
providing the substrate in a third substrate processing apparatus in a vacuum state;
forming a deposition suppressing layer on the substrate in the third substrate processing apparatus; and
unloading the substrate from the third substrate processing apparatus and exposing the substrate to a non-vacuum environment.

12. The method of claim 11, further comprising forming a liner layer on the substrate, after forming the second metal barrier in the second substrate processing apparatus.

13. A method of fabricating a semiconductor device, comprising:
providing an interlayer dielectric layer with a trench on a substrate in a first substrate processing apparatus in a vacuum state;
forming a deposition suppressing layer in the trench while the substrate is in the first substrate processing apparatus;
unloading the substrate from the first substrate processing apparatus to expose the substrate to a non-vacuum state;
providing the substrate in a second substrate processing apparatus of a vacuum state;
forming a first metal barrier in the trench, in the second substrate processing apparatus; and
forming a metal pattern to fill the trench.

14. The method of claim 13, wherein further comprising:
unloading the substrate from the second substrate processing apparatus and exposing the substrate to a non-vacuum environment;
providing the substrate in a third substrate processing apparatus of a vacuum state; and
forming a second metal barrier on the first metal barrier, in the third substrate processing apparatus,
wherein different methods are used to form the second metal barrier and the first metal barrier.

15. The method of claim 14, further comprising forming a seed layer on the second metal barrier in the third substrate processing apparatus,
wherein the seed layer comprises one of copper (Cu), titanium (Ti), ruthenium (Ru), molybdenum (Mo), tungsten (W), or copper alloy (Cu Alloy).

16. The method of claim 13, further comprising:
unloading the substrate from the second substrate processing apparatus and exposing the substrate to a non-vacuum environment;
providing the substrate in a third substrate processing apparatus of a vacuum state; and
forming a seed layer on the substrate.

17. The method of claim 16, further comprising forming a liner layer on the first metal barrier, before forming the seed layer on the substrate,
wherein the liner layer comprises cobalt (Co), ruthenium (Ru), or ruthenium-cobalt alloy (Ru—Co Alloy).

18. The method of claim 13, further comprising:
moving the substrate from the second substrate processing apparatus to a third substrate processing apparatus of a vacuum state; and
performing a post-treatment process in the third substrate processing apparatus.

19. The method of claim 18, further comprising:
moving the substrate from the second substrate processing apparatus to the third substrate processing apparatus of the vacuum state; and
performing a pre-cleaning process on the substrate in the third substrate processing apparatus.

20. The method of claim 19, further comprising:
unloading the substrate from the third substrate processing apparatus and exposing the substrate to a non-vacuum environment;
providing the substrate in a fourth substrate processing apparatus of a vacuum state; and
forming a liner layer on the first metal barrier, in the fourth substrate processing apparatus.
